(19) United States
(12) Patent Application Publication
(10) Pub. No.: US 2020/0098822 A1
(43) Pub. Date: Mar. 26, 2020

(54) MAGNETORESISTIVE RANDOM ACCESS MEMORY STRUCTURES HAVING TWO MAGNETIC TUNNEL JUNCTION ELEMENTS

(71) Applicant: Globalfoundries Singapore Pte. Ltd., Singapore (SG)

(72) Inventors: Eng Huat Toh, Singapore (SG); Bin Liu, Singapore (SG); Kiok Boone Elgin Quek, Singapore (SG)

(21) Appl. No.: 16/138,363

(22) Filed: Sep. 21, 2018

(51) Int. Cl. H01L 27/22; G11C 11/16; H01L 43/02; H01L 43/08; H01L 43/12

(52) U.S. Cl. CPC H01L 27/226; G11C 11/161; H01L 43/12; H01L 43/02; H01L 43/08; G11C 11/1675

(57) ABSTRACT

Magnetoresistive random access memory (MRAM) structures and arrays, methods for fabricating MRAM structures and arrays, and methods for operating MRAM structures and arrays are provided. An exemplary MRAM structure includes an access transistor having a source and a drain, a first magnetic tunnel junction (MTJ) element coupled to the source of the access transistor, and a second magnetic tunnel junction (MTJ) element coupled to the drain of the access transistor.

### TECHNICAL FIELD

The technical field generally relates to sophisticated semiconductor devices and the manufacturing of such devices, and, more specifically, to a magnetoresistive random access memory (MRAM) structure, such as a spin-transfer torque (STT) MRAM structure, including two magnetic tunnel junction elements to provide for storing multiple level states.

### BACKGROUND

Spin-transfer-torque magnetoresistive random access memory (STT MRAM) has been studied extensively and is now a prime candidate to serve as a universal memory as it is nonvolatile and could accommodate high endurance and low access time. Research has improved STT MRAM technology by reducing the switching current, eliminating the read disturbance issue, and resolving other device/cell challenges. Further, the high ratio between the high and low resistance of the cell has inspired interest in multi-level cell structures for STT MRAM.

However, STT MRAM technology is typically limited to binary on/off states. Thus, STT MRAM technology is not preferred when multiple level states are desired, such as for neuromorphic computing. Rather, phase-change memory (PCRAM) and resistive random-access memory (ReRAM) technologies have been utilized for multiple level states. Yet, MRAM has the advantage of faster speed, high endurance and better stability as compared to PCRAM and ReRAM.

Accordingly, it is desirable to provide an improved MRAM structure, such as an STT MRAM structure, and improved methods for fabricating such structures. It is also desirable to provide methods for fabricating multiple level state devices that are less expensive and less time consuming than current methods. Furthermore, other desirable features and characteristics will become apparent from the subsequent detailed description and the appended claims, taken in conjunction with the accompanying drawings and this background.

### BRIEF SUMMARY

Magnetoresistive random access memory (MRAM) structures and arrays, methods for fabricating MRAM structures and arrays, and methods for operating MRAM structures and arrays are provided. An exemplary MRAM structure includes an access transistor having a source and a drain, a first magnetic tunnel junction (MTJ) element coupled to the source of the access transistor, and a second magnetic tunnel junction (MTJ) element coupled to the drain of the access transistor.

In another embodiment, a magnetoresistive random access memory (MRAM) array is provided. The array includes a plurality of MRAM cells arranged in rows and columns, and each MRAM cell includes a first magnetic tunnel junction (MTJ) element, an access transistor, and a second magnetic tunnel junction (MTJ) element coupled in a serial connection. The array further includes a plurality of source lines. Each source line is coupled to the first MTJ element of a respective row of MRAM cells. Also, the array includes a plurality of bit lines. Each bit line is coupled to the second MTJ element of a respective column of MRAM cells.

In yet another exemplary embodiment, a method for fabricating a magnetoresistive random access memory (MRAM) structure is provided. The method includes forming an access transistor over a substrate. The access transistor has a gate located between a first source/drain region and a second source/drain region. The method further includes depositing magnetic tunnel junction (MTJ) layers over the substrate to form a first magnetic tunnel junction (MTJ) element coupled to the first source/drain region and a second magnetic tunnel junction (MTJ) element coupled to the second source/drain region.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

The various embodiments will hereinafter be described in conjunction with the following drawing figures, wherein like numerals denote like elements, and wherein:

FIGS. 1-4 are cross sectional schematic views of integrated circuit fabrication processing for forming an MRAM structure including two MTJ elements in accordance with an embodiment herein;

FIG. 5 is an overhead schematic view of an array of MRAM structures from FIG. 4 in accordance with embodiments herein;

FIG. 6 is a graph illustrating the combined resistance of exemplary MTJ elements in accordance with embodiments herein;

FIG. 7 is a graph illustrating the write currents for switching each MTJ element between parallel and anti-parallel states; and

FIGS. 8-11 are schematic diagrams illustrating various write operations for the MRAM structure of FIG. 4.

### DETAILED DESCRIPTION

The following detailed description is merely exemplary in nature and is not intended to limit the MRAM structures, MRAM arrays, methods for fabricating such structures and arrays, or methods for operating such structures and arrays described herein. Furthermore, there is no intention to be bound by any expressed or implied theory presented in the preceding technical field, background or brief summary, or in the following detailed description.

For the sake of brevity, conventional techniques related to conventional device fabrication may not be described in detail herein. Moreover, the various tasks and processes described herein may be incorporated into a more comprehensive procedure or process having additional functionality not described in detail herein. In particular, various processes in the fabrication memory devices are well-known and so, in the interest of brevity, many conventional processes will only be mentioned briefly herein or will be omitted entirely without providing the well-known process details. Further, it is noted that integrated circuits with MRAM devices, include a varying number of components and that single components shown in the illustrations may be representative of multiple components.

As used herein, it will be understood that when an element or layer is referred to as being “over” or “under” another element or layer, it may be directly on the other element or layer, or intervening elements or layers may be present. When an element or layer is referred to as being “on” another element or layer, it is directly on and in contact with the other element or layer. Further, spatially relative terms, such as “upper”, “over”, “under”, “lower”, “higher” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as being “under” other elements or features would then be oriented “above” the other elements or features. Thus, the exemplary term “under” can encompass either an orientation of above or below. The device may be otherwise oriented (rotated 90 degrees or at other orientations) and the spatially relative descriptors used herein may likewise be interpreted accordingly.

Further, as used herein, a layer identified as a “material layer” or as being a “material” includes at least 50 wt. % of the recited material. As used herein, a layer identified as a “primarily material layer” or as being “primarily material” is a layer that includes at least 90 wt. % of the recited material.

As will be readily apparent to those skilled in the art upon a complete reading of the disclosure, the devices disclosed herein may be employed with a variety of technologies, and may be incorporated into a variety of integrated circuit products. With reference to the attached drawings, various illustrative embodiments of the methods and devices disclosed herein will now be described in more detail. It should be understood that the various features and layers in the attached drawings may not be to scale.

Embodiments herein are directed towards MRAM structures, arrays of such structures, and various methods of fabricating or operating such structures or arrays. As described herein, an exemplary MRAM structure includes a transistor coupled on a source side to a first magnetic tunnel junction (MTJ) element and coupled on a drain side to a second magnetic tunnel junction (MTJ) element. In certain embodiments, the first MTJ element and the second MTJ element exhibit different thresholds for switching during WRITE operations. For example, the first MTJ element and the second MTJ element may be formed from identical material layers with identical thicknesses, but with two different widths, i.e., different critical dimensions, such that the energy for a WRITE operation to change the logic state of each MTJ element is different. Thus, in certain embodiments a first WRITE operation may be performed on one MTJ element before a second WRITE operation is performed on the other MTJ element. Further, logic states 00, 01, 10 and 11 provide four distinct resistance states, beneficial to applications such as synapse applications. It is noted that the critical dimension may be different in an X-direction and/or Y-direction, either of which may be referred to as width, with the understanding that the resulting different cross-sectional areas of the MTJ elements provide for different resistances for WRITE operations.

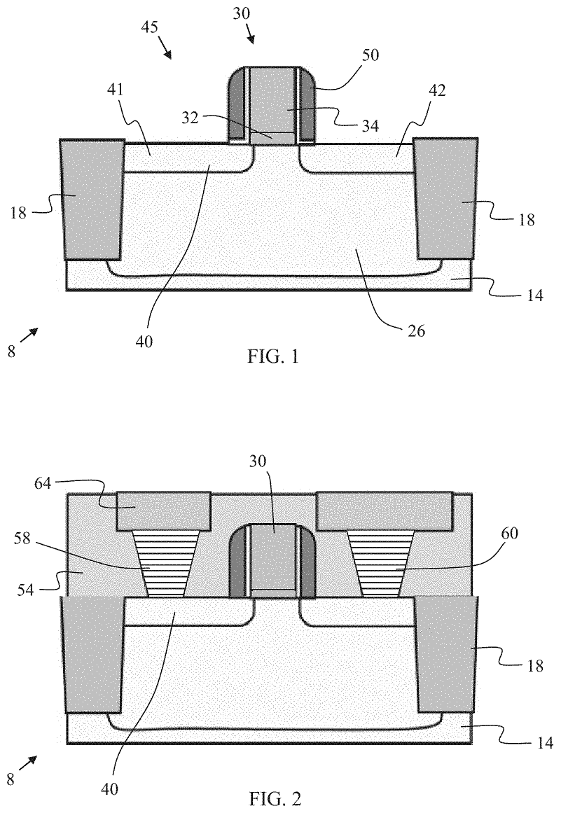

FIGS. 1-4 depict an embodiment of a method for fabricating an integrated circuit device 8, including a non-volatile memory structure. Specifically, the illustrated method may be used to fabricate a magnetoresistive random access memory (MRAM) structure. In FIG. 1, a partially fabricated integrated circuit device 8 is illustrated and is formed on or includes a substrate 14. An exemplary substrate 14 is a semiconductor substrate, such as a bulk silicon substrate. For example, the substrate 14 may be a lightly doped p-type substrate. Providing an intrinsic or other types of doped substrates, such as silicon-germanium (SiGe), germanium (Ge), gallium-arsenic (GaAs) or any other suitable semiconductor materials, may also be useful. In some embodiments, the substrate may be a semiconductor-on-insulator (SOI) or crystalline-on-insulator (COI) substrate. An SOI substrate includes a surface semiconductor layer separated from a semiconductor bulk material by an insulator layer. A COI substrate includes a surface crystalline layer separated from a crystalline bulk material by an insulator layer. The insulator layer, for example, may be formed of a dielectric insulating material. The insulator layer, for example, is formed from silicon oxide, which provides a buried oxide (BOX) layer. Other types of dielectric insulating materials may also be useful. The SOI or COI substrate, for example, may be a fully depleted silicon-on-insulator (FDSOI) substrate. For example, the thin surface and bulk crystalline layers are single crystalline silicon. Other types of SOI or COI substrates may also be useful. It is understood that the surface and bulk layers need not be formed of the same material.

As shown, the method may form isolation regions 18 in the substrate 14 according to conventional processing. Further, a well 26 may be formed in the substrate 14 according to conventional processing. In an exemplary embodiment, the well 26 is a p-type well formed by appropriate dopant implantation.

In FIG. 1, the method includes forming a gate structure 30. Specifically, the method includes the conventional processes of depositing a gate dielectric material over the substrate 14 and depositing a gate material over the gate dielectric material. Then, the gate dielectric material and gate material are masked and etched to form a gate dielectric layer 32 and a gate electrode 34 as shown.

After the gate etch, a liner oxidation process is performed, followed by a source drain extension doping process. Then, the liner and spacers are formed, followed by deep source/drain doping process.

As a result, source/drain extension regions (not independently illustrated). In an exemplary embodiment, the extension regions are doped with n-type dopants, i.e., the extension regions are n-doped regions. As is conventional, the implantation process may be performed using the gate structure 30 as a mask to dope the substrate 14 as desired.

As shown, spacers 50 are formed around the gate structure 30. For example, deposition and etching processes may be performed to form spacers 50 on the sidewalls of the gate structure 30. In an embodiment, the spacers 50 may be formed by depositing a conformal layer of dielectric/insulting material (e.g., silicon nitride or other suitable material) using known deposition methods, and then anisotropically etching the conformal layer of dielectric/insulating material to remove portions of the conformal layer on horizontal surfaces of the gate structure 30 and semiconductor substrate 14 to form the spacers 50 on vertical surfaces of the gate structure 30. The spacers 50 may include more than one layer of material, such as an underlying liner.

Also, source/drain regions 40 are formed, including a first source/drain region 41 and a second source/drain region 42, in the substrate 14 adjacent the gate structure 30. In an exemplary embodiment, the source/drain regions 40 are heavily doped with n-type dopants, i.e., the source/drain regions 40 are n⁺-doped regions. As is conventional, the implantation processes may be performed using the gate structure 30 as a mask to dope the substrate 14 as desired. As shown, the gate structure 30 is located between the first source/drain region 41 and the second source/drain region 42.

While spacer formation may be performed before, after, or at an intermediate stage of source/drain region formation, in the described embodiment, an initial source/drain extension implantation process is performed before spacer formation and the source/drain region implantation is performed after spacer formation.

In FIG. 1, the gate structure 30, first source/drain region 41 and the second source/drain region 42 form a transistor 45. The first source/drain region 41 may be a source or a drain and the second source/drain region 42 may be a drain or source, corresponding to the first source/drain region 41. As is conventional, a word line (not shown) may be formed, such as a word line strap, to contact the gate at different region. The poly gate structure 30 may be biased through the metal word line strap.

The method may continue in FIG. 2 with silicidation of surface portions of the source/drain regions 40 to form contact regions (not expressly labeled). The method further includes depositing and planarizing dielectric material to form an interlayer dielectric layer (ILD) 54. As shown, the ILD 54 is patterned and etched using conventional processing to form vias 58 that expose the contact regions of the source/drain regions 40. Thereafter, the vias 58 are filled with conductive material to form interconnects 60. Also, an additional metallization layer 64 may be formed in or over the ILD 54 and in electrical contact with the interconnects. The metallization layer 64 may be considered to form bottom electrodes. As is customary, the device 8 may include multiple levels of ILD layers and metallization layers.

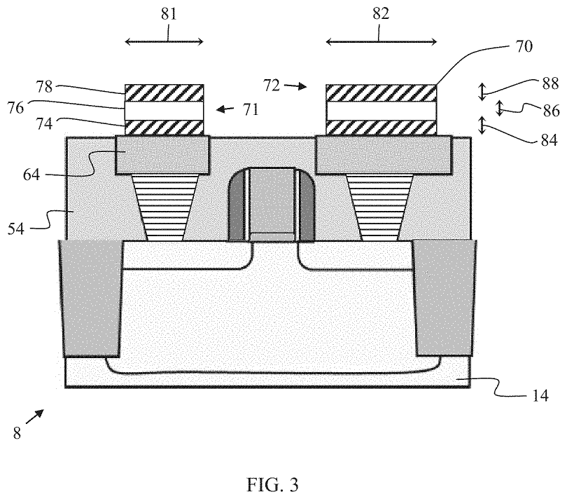

In FIG. 3, the method continues with the formation of two distinct magnetic tunnel junction (MTJ) elements 70, e.g., first MTJ element 71 and second MTJ element 72. As shown, each MTJ element 70 is formed on a respective metallization layer 64. Further, each MTJ element 70 is formed as a stack of identical layers. As illustrated, each MTJ element 70 includes a magnetically fixed layer or polarizer layer 74, a tunnel barrier layer 76, and a magnetically free layer or storage layer 78. The MTJ elements 70 may include other layers including seed layers, wetting layers, spacer layers, anti-ferromagnetic layers, additional tunnel barrier layers, and the like. It is realized that the MTJ elements 70 may include MTJ layers of many variations that are within the scope of the present disclosure.

In the illustrated embodiment, the magnetically fixed layer 74 is disposed below the magnetically free layer 78, forming a bottom pinned MTJ stack. In other embodiments, the fixed layer 74 may be located above the free layer 78 and form a top pinned MTJ stack. The magnetic orientation of fixed layer 74 is fixed in a first perpendicular direction. The term perpendicular direction refers to the direction that is perpendicular to the surface of a substrate or perpendicular to the plane of the layers of the MTJ stack. As shown, the first perpendicular direction is in an upward direction away from the substrate. Providing the first perpendicular direction in a downward direction towards the substrate may also be useful in alternative embodiments. The magnetic orientation of free layer 78 may be programmed to be in a first or same direction as fixed layer 74 or in a second or opposite direction as fixed layer 74.

In the method, the layers 74, 76, and 78 are successively deposited over the ILD 54 and metallization layer 64. Thereafter, the layers 74, 76, and 78 may be patterned by masking and etching to form the two distinct stacks of the MTJ elements 71 and 72. Thus, the first MTJ element 71 and the second MTJ element 72 include a concurrently deposited layer 74 that is later etched into the distinct stacks of the MTJ elements 70. Further, the first MTJ element 71 and the second MTJ element 72 include a concurrently deposited layer 76 that is later etched into the distinct stacks of the MTJ elements 70. Also, the first MTJ element 71 and the second MTJ element 72 include a concurrently deposited layer 78 that is later etched into the distinct stacks of the MTJ elements 70. Accordingly, the first MTJ element 71 and the second MTJ element 72 includes a same thickness 84 of layer 74, a same thickness 86 of layer 76, and a same thickness 88 of layer 78.

However, as shown, the first MTJ element 71 and the second MTJ element 72 may be formed by masking and etching the stack of layers 74, 76 and 78 to different widths or critical dimensions such that the first MTJ element 71 and the second MTJ element have different cross-sectional areas along a contact plane (in FIG. 3, a horizontal plane perpendicular to the drawing sheet). Specifically, first MTJ element 71 may have a first width 81 and second MTJ element 72 may have a second width 82. In FIG. 3, second width 82 is greater than first width 81. For example, the first width 81 may be from about 40 to about 90 nanometers (nm) and the second width 82 may be from about 60 to about 120 nm. In certain embodiments, the first width 81 may be from about 50 to about 70 nm, such as about 60 nm, and the second width 82 may be from about 70 to about 90 nm, such as about 80 nm. In other embodiments, the first width 81 may be from about 70 to about 90 nm, such as about 82 nm, and the second width 82 may be from about 100 to about 120 nm, such as about 114 nm. In an exemplary embodiment, the second width 82 is at least about 10% greater than first width 81—such as at least about 20% greater, for example at least about 30% greater, or at least about 33% greater, than first width 81. In an exemplary embodiment, the second width 82 is no more than 100% greater than first width 81—such as no more than about 50% greater, for example no more than about 40% greater, than first width 81. The stack of layers 74, 76 and 78 may have a same depth in the first MTJ element 71 and the second MTJ element 72, such that the difference in width between MTJ elements 70 is directly related to the different in cross-sectional area between MTJ elements 70.

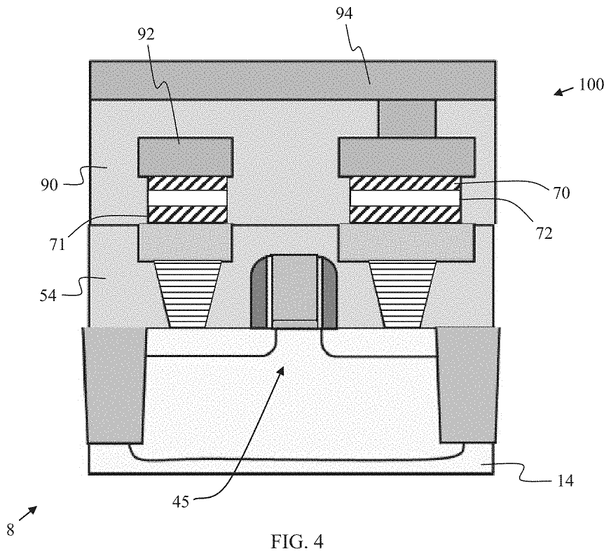

In FIG. 4, the method continues with formation of another interlayer dielectric (ILD) 90 over the ILD 54 and MTJ elements 70. As shown, metallization layers are formed and patterned to form a source line (SL) 92 coupled to the first MTJ element 71 and a bit line (BL) 94 coupled to the second MTJ element 72. Bit line 94 may be coupled to the second MTJ element 72 through multiple levels of metallization. Such processes may be performed during typical back end of line (BEOL) processing. During design and fabrication of the integrated circuit device 8, the locations of the source line 92 and bit line 94 may be reversed such that the bit line 94 is coupled to the first MTJ element 71 and the source line 92 is coupled to the second MTJ element 72.

FIG. 4 illustrates an integrated circuit device 8 including an exemplary MRAM structure 100 including two MTJ elements 70. An exemplary MRAM structure 100 is a spin-transfer torque STT MRAM structure. As shown, a serial connection is formed from the first MTJ element 71 to the transistor 45 to the second MTJ element 72. Further, the first MTJ element 71 is coupled to the source line 92 and the second MTJ element is coupled to the bit line 94.

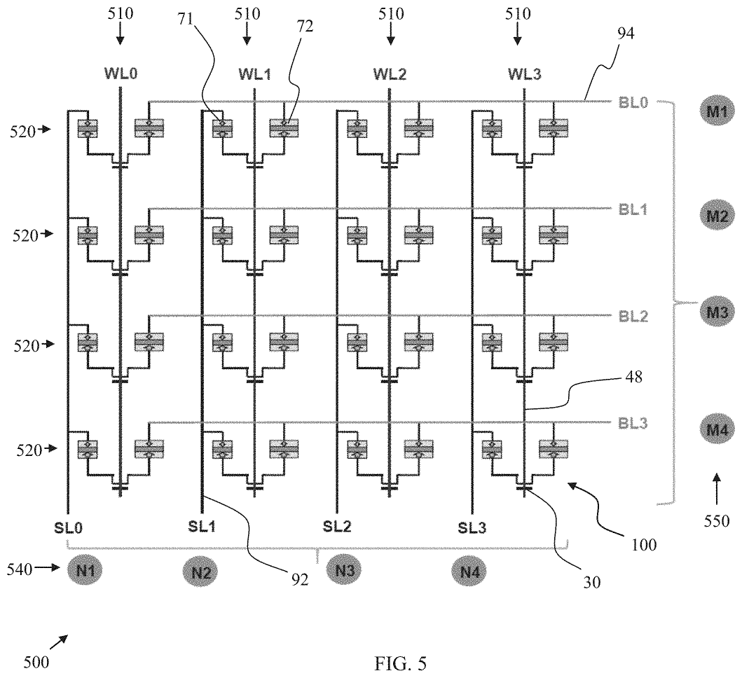

FIG. 5 illustrates an array 500 of MRAM cells or structures 100 as described in FIGS. 1-4 arranged in columns 510 and rows 520. As shown, the first MTJ elements 71 of MRAM structures 100 in a common column 510 are coupled to a same source line 92, such as source lines SL0, SL1, SL2 or SL3. Also, the gate structures 30 of MRAM structures 100 in a common column 510 are coupled to a same word line 48, such as word lines WL0, WL1, WL2 or WL3. Further, the second MTJ elements 72 of MRAM structures 100 in a common row 520 are coupled to a same bit line 94, such as bit lines BL0, BL1, BL2 or BL3. It is noted that different arrangements may used, including bit lines parallel to source lines, shared source lines, or other suitable layouts.

FIG. 5 further illustrates that the array 500 may be utilized in neuromorphic computing by coupling the source lines 92 to first neuromorphic circuitry indicated by nodes 540 and by coupling the bit lines 94 to neuromorphic circuitry indicated by nodes 550. With this arrangement, the MRAM structures 100, having multiple level states, can be used as synapses in neuromorphic computing.

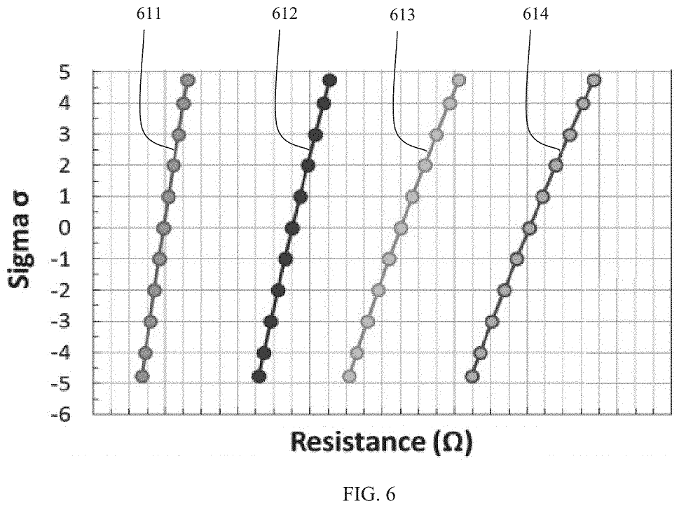

FIG. 6 is a graph illustrating the normalized resistance of each possible combination of logic states (or resistance states) for the MTJ elements 70 of an exemplary MRAM structure 100 at various standard deviations, represent by sigma (σ). In the graph, the resistance increases from left to right. For a normal distribution, 97% of the population will be within +/−3σ. For the MRAM structure 100 of FIGS. 4 and 5, the serial coupling of the first MTJ element 71, gate structure 30, and second MTJ element 72 provides for four distinct resistance states, which may be beneficial for synapse applications, such as in neuropathic circuitry. The combined resistance of logic 00 wherein the first MTJ element 71 is at logic 0 (i.e., the low resistance state) and the second MTJ element 72 at logic 0 (i.e., the low resistance state) may be referred to as R_{LL} and is identified by the points forming line 611. The combined resistance of logic 01 wherein the first MTJ element 71 is at logic 0 (i.e., the low resistance state) and the second MTJ element 72 at logic 1 (i.e., the high resistance state) may be referred to as R_{LH} and is identified by the points forming line 612. The combined resistance of logic 10 wherein the first MTJ element 71 is at logic 1 (i.e., the high resistance state) and the second MTJ element 72 at logic 0 (i.e., the low resistance state) may be referred to as R_{HL} and is identified by the points forming line 613. The combined resistance of logic 10 wherein the first MTJ element 71 is at logic 1 (i.e., the high resistance state) and the second MTJ element 72 at logic 1 (i.e., the high resistance state) may be referred to as R_{HH} and is identified by the points forming line 614.

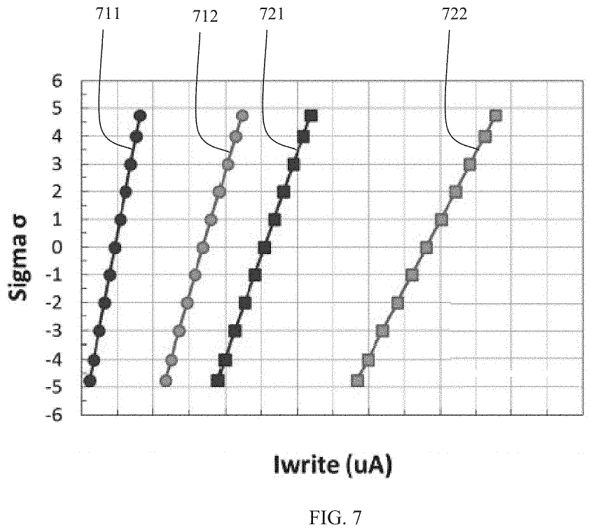

FIG. 7 is a graph illustrating the normalized write current (Iwrite) necessary for switching the logic states for each MTJ element. In the graph, the write current increases from left to right. For example, the write current for switching the first MTJ element from anti-parallel (logical high) to parallel (logical low), or AP-to-P, is identified by the points forming line 711. The write current for switching the first MTJ element from parallel (logical low) to anti-parallel (logical high), or P-to-AP, is identified by the points forming line 712. The write current for switching the second MTJ element from anti-parallel to parallel (AP-to-P) is identified by the points forming line 721. The write current for switching the second MTJ element from parallel to anti-parallel (P-to-AP) is identified by the points forming line 722. Thus, it may be seen that at any particular sigma, the write current is higher for switching the second MTJ element; and for each MTJ element, the write current is higher for switching from parallel to anti-parallel (P-to-AP) as compared to switching from anti-parallel to parallel (AP-to-P).

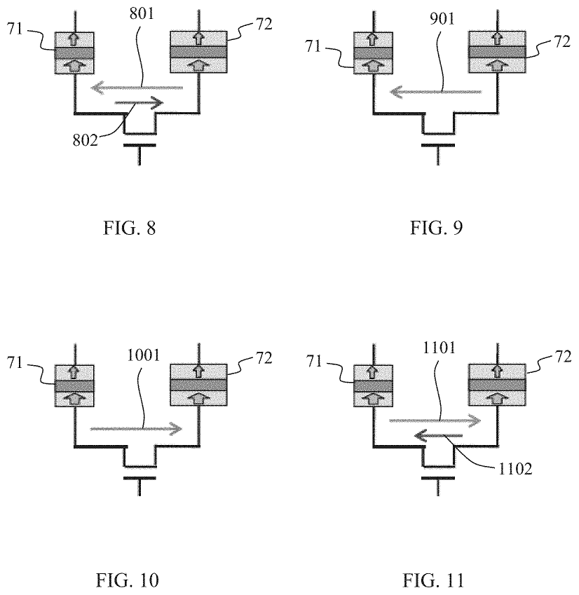

FIGS. 8-11 are simplified schematic diagrams illustrating embodiments for writing various memory states in an exemplary STT MRAM structure. For example, FIG. 8 illustrates how to write logic 00. When writing logic 00, a first write operation, applies a first current in the direction indicated by arrow 801 to switch the second MTJ element 72 from anti-parallel state to parallel state (i.e., logical low state). Then, a second write operation applies a second current in the direction indicated by arrow 802 to switch the first MTJ element 71 from anti-parallel state to parallel state (i.e., logical low state).

It is noted that the switching current required for second MTJ element 72 is larger than that of first MTJ element 71 due to the larger critical dimension of second MTJ element 72. To achieve 00, a first write current 801 flowing in the direction indicated is used to switch second MTJ element 72 from AP to P. This current is high enough to switch second MTJ element 72 from AP to P (state 0) and first MTJ element 71 from P to AP (state 1). Note the current flowing through the second MTJ element free layer, then the second MTJ element fixed layer, then the first MTJ element fixed layer, then the first MTJ element free layer). As such, to switch first MTJ element 71 to the desired P (state 0), a lower 2^{nd} write current 802 in the opposite direction is employed. Current 802 is low enough that the state of second MTJ element 72 will not be changed but high enough to switch first MTJ element 71 from AP to P (state 0), thereby achieving logic 00. It is noted that when writing logic 00, and optional read process may be used to read verify logic 00 before write currents are applied. If logic 00 is read, then no write current need be applied. If any other logic state is read, then the first and second write operations may be performed as described.

FIG. 9 illustrates an embodiment for writing logic 01. To write logic 01, a single concurrent write operation is performed. Specifically, a write operation applies a write current in the direction indicated by arrow 901 to switch the second MTJ element 72 from parallel state to anti-parallel state (i.e., logical high state) and the first MTJ element 71 from anti-parallel state to parallel state (i.e., logical low state). To achieve logic state 01, one write current 901 in the direction shown is applied. Applying current 901 as illustrated causes second MTJ element 72 to switch from AP to P and causes first MTJ element 71 to switch from P to AP, as the current 901 is higher than the critical switching current of both MTJ elements 71 and 72 in their respective directions. In this case, the switching current of the second MTJ element 72 will be the limiting factor. Thus, a current higher than the switching current of second MTJ element 72 is used, and this current will in turn be higher than the switching current of the first MTJ element 71 (first MTJ element 71 has a smaller size so a lower switching current is needed).

FIG. 10 illustrates an embodiment for writing logic 10. To write logic 10, a single concurrent write operation is performed. Specifically, a write operation applies a write current in the direction indicated by arrow 1001 to switch the first MTJ element 71 from parallel state to anti-parallel state (i.e., logical high state) and the second MTJ element 72 from anti-parallel state to parallel state (i.e., logical low state). To write logic state 10, a current 1001 is applied in the opposite direction of current 901 from FIG. 9. Current 1001 causes second MTJ element 72 to switch from AP to P and causes first MTJ element 71 to switch from P to AP. Again, the larger switching current of the second MTJ element 72 is the limitation, and a current higher than the switching current of the second MTJ element 72 is applied to switch both MTJ elements 71 and 72 to their respective desired states.

FIG. 11 illustrates an embodiment for writing logic 11. To write logic 11, a first write operation applies a first write current in the direction of arrow 1101 to switch the second MTJ element 72 from parallel state to anti-parallel state (i.e., logical high state). Then, a second write operation applies a second write current in the direction of arrow 802 to switch the first MTJ element 71 from parallel state to anti-parallel state (i.e., logical high state). To achieve a logic 11 state, the limiting switching current is that needed to switch the second MTJ element 72 from P to AP. As such, a first high current 1101 in the direction indicated is applied to switch the second MTJ element 72 from P to AP. Current 1101 is high enough to switch first MTJ element 71 from AP to P. As such, to correct the state of first MTJ element 71, a smaller current 1102 in the opposite direction is applied. Current 1102 is high enough to switch first MTJ element 71 from P to AP, but small enough that the state of the second MTJ element 72 is not changed, as the switching current required for second MTJ element 72 is much higher than that of the first MTJ element 71. When writing logic 11, a read process can be used to optimize the write operation. For example, if logic 11 is read, then no write current need be applied. If logic 01 is read, then only the write operation, indicated by arrow 802, is performed to switch the first MTJ element 71 from parallel state to anti-parallel state (i.e., logical high state). If logic 00 or logic 10 are read, then both the first and second write operations are performed as described.

The following Write Bias Table summarizes the write operations of FIGS. 8-11:

| State | First MTJ element | Second MTJ element |
|---|---|---|
| R_{LL} (00) | 2^{nd} AP-P | 1^{st} AP-P |
| R_{LH} (01) | Concurrent AP-P | Concurrent P-AP |
| R_{HL} (10) | Concurrent P-AP | Concurrent AP-P |
| R_{HH} (11) | 2^{nd} P-AP | 1^{st} P-AP |

As described herein, an exemplary MRAM structure, such as an STT MRAM structure, is provided with the capability of storing multiple level states, e.g., logic states 00, 01, 10 and 11. The exemplary MRAM structure utilizes two MTJ elements having different resistances such that four different combined resistances are achieved. In exemplary embodiments, the MTJ elements are fabricating using identical processing and components, except for the width that the MTJ elements are etched to. Thus, a simplified fabrication process may be used to form the exemplary MRAM structure. Further, the processes described herein are similar to processes in conventional CMOS processing such that necessary process equipment and actions are available.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration as claimed in any way. Rather, the foregoing detailed description will provide those skilled in the art with a convenient road map for implementing the exemplary embodiment or exemplary embodiments. It should be understood that various changes can be made in the function and arrangement of elements without departing from the scope herein as set forth in the appended claims and the legal equivalents thereof.

1. A magnetoresistive random access memory (MRAM) structure comprising:
an access transistor having a source and a drain;
a first magnetic tunnel junction (MTJ) element coupled to the source of the access transistor; and
a second magnetic tunnel junction (MTJ) element coupled to the drain of the access transistor.

2. The MRAM structure of claim 1, wherein the first MTJ element has a first critical dimension and the second MTJ element has a second critical dimension different from the first critical dimension.

3. The MRAM structure of claim 1, wherein the first MTJ element and the second MTJ element are formed from a stack of concurrently deposited layers, wherein each MTJ element includes a same thickness of each layer.

4. The MRAM structure of claim 1, further comprising:
a source line coupled to the first MTJ element; and
a bit line coupled to the second MTJ element.

5. The MRAM structure of claim 1, further comprising:
a bit line coupled to the first MTJ element; and
a source line coupled to the second MTJ element.

6. The MRAM structure of claim 1 wherein the access transistor includes a gate between the source and the drain, and wherein the MRAM structure further comprises:
a word line coupled to the gate of the access transistor; and
a bit line and a source line coupled to respective MTJ elements.

7. The MRAM structure of claim 1, further comprising:
a bit line and a source line coupled to respective MTJ elements;
first neuromorphic circuitry coupled to the source line; and
second neuromorphic circuitry coupled to the bit line.

8. The MRAM structure of claim 1 wherein the MRAM structure is a spin-transfer torque (STT) MRAM structure.

9. A magnetoresistive random access memory (MRAM) array comprising:
a plurality of MRAM cells arranged in rows and columns, wherein each MRAM cell comprises a first magnetic tunnel junction (MTJ) element, an access transistor, and a second magnetic tunnel junction (MTJ) element coupled in a serial connection;
a plurality of source lines, wherein each source line is coupled to the first MTJ element of a respective row of MRAM cells; and
a plurality of bit lines, wherein each bit line is coupled to the second MTJ element of a respective column of MRAM cells.

10. The MRAM array of claim 9 wherein each access transistor includes a gate and wherein the MRAM array further comprises a plurality of word lines, wherein each word line is coupled to the gate of a respective column of MRAM cells.

11. The MRAM array of claim 9 wherein each access transistor includes a gate located between a first source/drain region and a second source/drain region, wherein in each MRAM cell the first MTJ element is coupled to the first source/drain region and the second MTJ element is coupled to the second source/drain region.

12. The MRAM array of claim 9 wherein each access transistor includes a gate located between a first source/drain region and a second source/drain region, wherein in each MRAM cell the first MTJ element is coupled to the first source/drain region and the second MTJ element is coupled to the second source/drain region, and wherein the MRAM array further comprises a plurality of word lines, wherein each word line is coupled to the gate of a respective column of MRAM cells.

13. The MRAM array of claim 9 wherein each first MTJ element has a first critical dimension and each second MTJ element has a second critical dimension different from the first critical dimension.

14. The MRAM array of claim 9 wherein each first MTJ element and each second MTJ element are formed from a stack of concurrently deposited layers, wherein each MTJ element includes a same thickness of each layer.

15. The MRAM array of claim 9 wherein each first MTJ element and each second MTJ element are formed from a stack of concurrently deposited layers, wherein each MTJ element includes a same thickness of each layer, and wherein each first MTJ element has a first critical dimension and each second MTJ element has a second critical dimension different from the first critical dimension.

16. The MRAM array of claim 9 further comprising:
first neuromorphic circuitry coupled to the plurality of source lines; and
second neuromorphic circuitry coupled to the plurality of bit lines.

17. A method for fabricating a magnetoresistive random access memory (MRAM) structure, the method comprising:
forming an access transistor over a substrate, wherein the access transistor has a gate located between a first source/drain region and a second source/drain region; and
depositing magnetic tunnel junction (MTJ) layers over the substrate to form a first magnetic tunnel junction (MTJ) element coupled to the first source/drain region and a second magnetic tunnel junction (MTJ) element coupled to the second source/drain region.

18. The method of claim 17 further comprising:
depositing a dielectric layer over the substrate;
planarizing the dielectric layer;
etching the dielectric layer to form a first contact opening over the first source/drain region and to form a second contact opening over the second source/drain region; and
forming a first contact to the first source/drain region through the first contact opening and a second contact to the second source/drain region through the second contact opening, wherein depositing the MTJ layers over the substrate comprises depositing the MTJ layers over the first contact and the second contact.

19. The method of claim 18 further comprising etching the MTJ layers to form the first MTJ element with a first width of the MTJ layers and to form the second MTJ element with a second width of the MTJ layers, wherein the second width is different from the first width.

20. The method of claim 17 further comprising:
forming a source line over the substrate and electrically coupled to the first MTJ element; and
forming a bit line over the substrate and electrically coupled to the second MTJ element.
